(19) United States
(12) Patent Application Publication
(10) Pub. No.: US 2013/0073920 A1
(43) Pub. Date: Mar. 21, 2013

(54) IMPLEMENTATION-ORIENTED METHOD OF BICM BASED ON LDPC CHECK MATRIX

(71) Applicants: Yuanfei NIE, Shanghai (CN); Gang HU, Shanghai (CN)

(72) Inventors: Yuanfei NIE, Shanghai (CN); Gang HU, Shanghai (CN)

(73) Assignee: MONTAGE TECHNOLOGY (SHANGHAI) CO., LTD., Shanghai (CN)

(21) Appl. No.: 13/482,507

(22) Filed: May 29, 2012

(30) Foreign Application Priority Data
Sep. 20, 2011 (CN) 201110280872.4

(51) Int. Cl. H03M 13/11; G06F 11/10

(52) U.S. Cl. 714/752; 714/E11.032

(57) ABSTRACT

An IMPLEMENTATION-ORIENTED METHOD of Bit Interleaved Coded Modulation (BICM) based on a Low-Density Parity-Check (LDPC) check matrix including constructing an LDPC code having a block check matrix or providing an existing LDPC, where the block check matrix is divided into one or more sub-matrixes Hᵢⱼ with the size being B*B, constructing a BICM structure; in the BICM structure mapping an i^{th} bit sequence [bitps(i,0), . . . , bitps(i,m−1)] with a length being m to obtain a mapping symbol s(i), where the size of a set of the mapping symbols s(i) is 2^{m}; enabling mapping bits of all the mapping symbols s(i) of a mapping symbol subset S, =[s,(0), . . . s(i), . . . s(B−1)] to correspond to m check sub-matrixes. The mapping bits at the same position correspond to the same check sub-matrix, the number of which is m. Subsequently a receiver reads bit external information blocks corresponding to the mapping symbols during parallel soft demodulation, thereby implementing decoding feedback and fully exerting a joint receiving performance.

### BACKGROUND OF THE PRESENT INVENTION

1. Field of Invention

The present invention relates to bit interleaved coded technologies, and more particular to design an implementation-oriented scheme of Bit Interleaved Coded Modulation (BICM) based on a Low-Density Parity-Check (LDPC) check matrix.

2. Description of Related Arts

During transmission of signals in a channel, a transmission medium or other signal sources may introduce a series of influences to the signals, such as attenuation, distortion, interferences and noises, which cause error decision in a receiving end. Particularly, the influences are greater in satellite communications, deep space communications and various radio communication systems. In order to improve the anti-interference capability of the communication system, channel encoding is indispensable. A code stream is correspondingly processed through manners such as channel encoding and interleaving, which may greatly reduce Bit Error Rate (BER).

In current channel encoding systems, an LDPC code is a code closest to Shannon channel capacity limit, and the performance of the LDPC code is better than that of a turbo code in respect of medium-long codes.

The decoding of the LDPC code adopts an iterative decoding algorithm based on Belief Propagation (BP), which not only has desirable decoding performance but also has linear decoding complexity (the decoding complexity is low), more importantly, has the features comprising capability of parallel decoding (which greatly improves a decoding speed) and capability of detecting errors of decoding, and thus becomes a research focus of the current channel encoding theory.

FIG. 1 is a block diagram of encoding by using LDPC codes in the prior art. As shown in FIG. 1, block encoding (or referred to as layered encoding) is first performed on information bits generated by an information source to obtain an encoded sequence, the encoded sequence is interleaved and then mapped to a constellation through an interleaver which is independent of the code check matrix, and input to a modulator for modulation, and finally, signals after modulation is sent to the outside.

An LDPC check matrix of a block structure (or referred to as a layered structure) may be described in the following:

$$H = [ \begin{matrix}{H}_{00} & ⋯ & {H}_{0 q} \\ ⋮ & ⋱ & ⋮ \\ {H}_{p 0} & ⋯ & {H}_{pq}\end{matrix} ]$$

Here, a sub-matrix in row i column j is marked as Hᵢⱼ with a size of B×B, which is a zero matrix, a unit matrix, a matrix obtained through displacement of the unit matrix, or a matrix obtained through superposition of the basic matrixes.

The LDPC code of such a structure is easily implemented in parallel in decoding, and the existing standards all belong to this kind. As for the sub-matrix, a bit set corresponding to all non-zero elements is marked as Ω(i,j).

As for the structure of the researched or used bit interleaved LDPC encoding, the receiver generally adopts the manner of performing soft demodulation and soft decoding separately. If iterative decoding feedback is used, an implementation schematic view is as shown in FIG. 2, which illustrates a relation among bits, mapping symbols and check sub-matrixes in a conventional BICM system.

As shown in FIG. 2, a bit sequence [bitps(i,0), . . . , bitps(i,m−1)] with a length being m is mapped in a certain mapping manner to obtain a mapping symbol s(i), the size of a set of the mapping symbols is 2^{m}, a generally used mapping method is Gray mapping, and the transmission performance of the obtained mapping symbols may be improved through manners such as rotation or spread, spectrum. If the receiver uses the iterative decoding feedback, the first mapping bit of each element in a subset Sᵣ=[s(0), . . . s(i), . . . s(B−1)] of the mapping symbols may correspond to a check sub-matrix Hij, which means that once parallel decoding with the participation of Hij in parallel decoding is over, the obtained bit external information may participate in the soft demodulation. However, the update of the bit information during demodulation also needs the external information of other bits. Referring to FIG. 2, the last mapping bit of each element in a subset of the mapping symbols corresponds to a different check sub-matrix (for example, bitps(0,m−1) corresponds to the check sub-matrix Hₗₖ, and bitps(B−1,m−1) corresponds to the check sub-matrix H_{tf}). And in this way, if the soft demodulation of the subset Sᵣ=[s (0), . . . s(i), . . . s(B−1)] of the mapping symbols is implemented under the iterative decoding feedback, the check sub-matrix corresponding to the bit external information required to be collected is larger than m. Further, in order to implement parallel soft demodulation, a bit access block to be read is still larger than in m, the number of corresponding clocks occupying joint iterative demodulation is increased, resulting in a reduced throughput rate. Moreover, there is merely one mapping symbol subset considered in the above illustration, however, in actual application, the update of all the symbols is required. In this way, the corresponding accessor read-write conflict processing and address control may be too complex to be implemented, or a great loss occurs in the performance even if the implementation is achieved.

### SUMMARY OF THE PRESENT INVENTION

An objective of the present invention is to provide an IMPLEMENTATION-ORIENTED METHOD of BICM based on an LDPC check matrix, for overcoming the defects existing in prior art, such as a great number of bit access blocks being read by the receiver during both soft demodulation process and soft decoding process, corresponding increased clock number occupation of joint iterative demodulation, and a reduced throughput rate it may cause.

The present invention provides an IMPLEMENTATION-ORIENTED METHOD of BICM based on an LDPC check matrix, which comprises steps of:

providing an LDPC code having a block check matrix, wherein the block check matrix is divided into one or more sub-matrixes Hᵢⱼ, and the size of the sub-matrix Hᵢⱼ is C*C;

constructing a BICM structure;

in the BICM structure, mapping an i^{th} bit sequence [bitps(i,0), . . . , bitps(i, m−1)] with the length being in to obtain a mapping symbol s(i), wherein the size of a set of the mapping symbols s(i) is 2^{m}; and

enabling mapping bits of a subset Sᵣ=[s(0), . . . s(i), . . . s(C−1)] of the mapping symbols to correspond to m check sub-matrixes.

Optionally, the enabling the mapping bits of the subset Sᵣ=[s(0), . . . s(i), . . . s(C−1)] of the mapping symbols to correspond to m check sub-matrixes comprises: enabling mapping bits at the same position in all the mapping symbols s(i) of the subset Sᵣ=[s(0), . . . s(i), . . . s(C−1)] of the mapping symbols to correspond to the same check sub-matrix, wherein the number of the check sub-matrixes is m.

Optionally, in the BICM structure, a mapping manner of an interleaver comprises:

Π={Iᵢₙ(i),i=0, . . . , N−1}→{Iₒᵤₜ(i),i=0, . . . , N−1},

wherein, Iᵢₙ is a time index of an input bit, and Iₒᵤₜ is a time index of a corresponding output bit; and

the interleaver is decomposed as follows:

Π=Π₀∪Π₁∪ . . . ∪Π_{κ},

wherein, Πᵢ∪Πⱼ=Null, if i≠j, 0≦i, j<κ.

Optionally, the input of each sub-interleaver corresponds to one check sub-matrix, that is:

∀i, Πᵢ:Iₘ(i)→Iₒ(i),0≦i<κ,

Iₘ(i)={Iᵢₙ(map1(i,j)), j=0, . . . , C−1},

Iₒ(i)={Iₒᵤₜ(map2(i,j)), j=0, . . . , C−1},

∃l,t, Iₘ(i) [symbol] Ω(l,t);

wherein, map1(i,j) represents an input time index corresponding to the j^{th} bit of the i^{th} sub-interleaver, and map2(i,j) represents an output time index corresponding to the j^{th} bit of the i^{th} sub-interleaver.

Optionally, classification of the sub-interleavers is as follows and the number of the classifications is L:

$$Γ = {⋃}_{0 \leq k < L} {Γ}_{k} , 0 < L \leq κ , {Γ}_{k} ⊆ \{ 0 , 1 , … , κ - 1 \}$$

$$if 0 \leq i , j < L , i \neq j , {Γ}_{i} ⋂ {Γ}_{j} = Null ,$$

wherein, an output bit set of a sub-interleaver corresponding to each classification may be fully mapped onto the corresponding symbol.

Optionally, a mapping rule corresponding to the output of the sub-interleaver comprises:

$$∀ i , j , k , 0 \leq j , k < m - 1 , 0 \leq i < \frac{N}{m} - 1 , j \neq k , 0 \leq l , t < κ$$

$$if bitps ( i , j ) ∈ {I}_{0} ( l ) , bitps ( i , k ) ∈ {I}_{0} ( t )$$

$$then , l \neq t .$$

Optionally, the mapping manner of the sub-interleaver comprises group interleaving, convolutional interleaving or S interleaving.

Optionally, the size of the sub-matrix Hᵢⱼ is the size of the greatest sub-matrix B*B of the check matrix or a submultiple

$$\frac{B}{sub} * \frac{B}{sub}$$

of the greatest sub-matrix, wherein sub and

$$\frac{B}{sub}$$

both are an integers.

Optionally, the bit sequence [bitps(i,0), . . . , bitps(i,m−1)] is mapped to obtain the mapping symbol s(i) through the following mapping manners: Gray mapping, multi-dimensional mapping, non-Gray mapping or higher level constellation modulation.

In the IMPLEMENTATION-ORIENTED METHOD of BICM based on the LDPC check matrix, each bit sequence [bitps(i,0), . . . , bitps(i, m−1)] with the length being m is mapped to obtain the mapping symbol s(i), and the mapping bits at the same position in all the mapping symbols correspond to the same check sub-matrix (that is, the check sub-matrix at the same mark is mapped onto the mapping bits at a certain mark in all the mapping symbols s(i)). In this way, subsequently the receiver easily reads the bit external information blocks corresponding to the mapping symbols during parallel soft demodulation, thereby easily implementing decoding feedback and fully exerting joint receiving performance.

### BRIEF DESCRIPTION OF THE DRAWINGS

FIG. 1 is a block diagram of encoding by using LDPC codes in the prior art;

FIG. 2 illustrates a relation among bits, mapping symbols and check sub-matrixes in a BICM system in the prior art;

FIG. 3 is a schematic view of a relation among bits, mapping symbols and check sub-matrixes in a novel BICM structure according to the present invention; and

FIG. 4 is a state view of interleaving and mapping by a bit interleaver depending on an

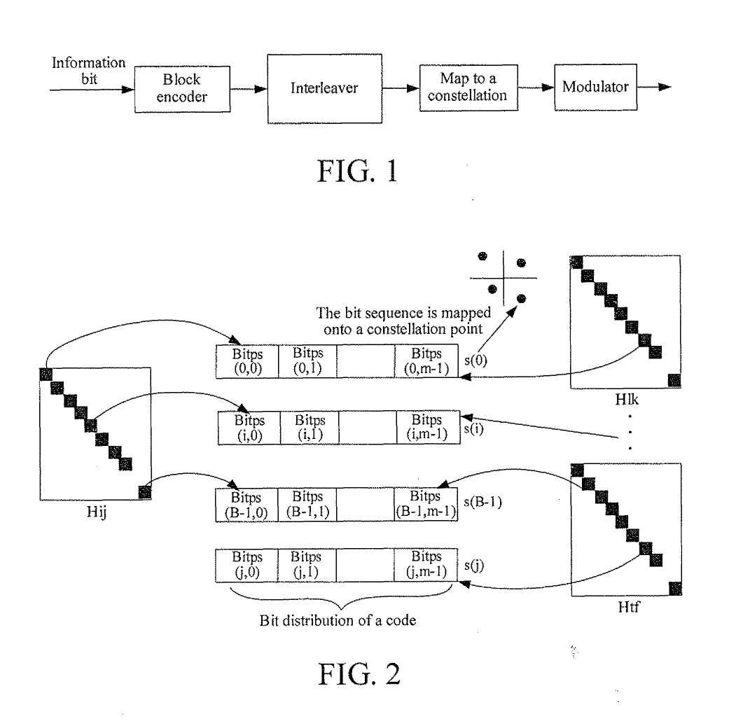

LDPC check matrix.

### DETAILED DESCRIPTION OF THE PREFERRED EMBODIMENTS

In the prior art, since mapping bits of mapping symbols in a subset of the mapping symbols may correspond to different multiple check sub-matrixes, causing that a receiver needs to read more bit access blocks when using iterative decoding feedback for parallel decoding, the number of corresponding clocks occupying joint iterative demodulation is increased, a throughput rate is reduced, the processing complexity is increased, and decoding performance is reduced.

Therefore, inventors of the present invention improve the prior art, so that the interleaver depends on a constructed LDPC code check matrix, and a check sub-matrix at the same mark in the check matrix is mapped to a mapping bit at a certain mark in all mapping symbols s(i), which can implement parallel soft demodulation. In this way, the receiver does not need to read more bit external information blocks during parallel soft demodulation, thereby easily implementing encoding feedback and fully exerting joint receiving performance.

A collaborative spectrum sensing method provided by the present invention is described in detail in the following through specific embodiments.

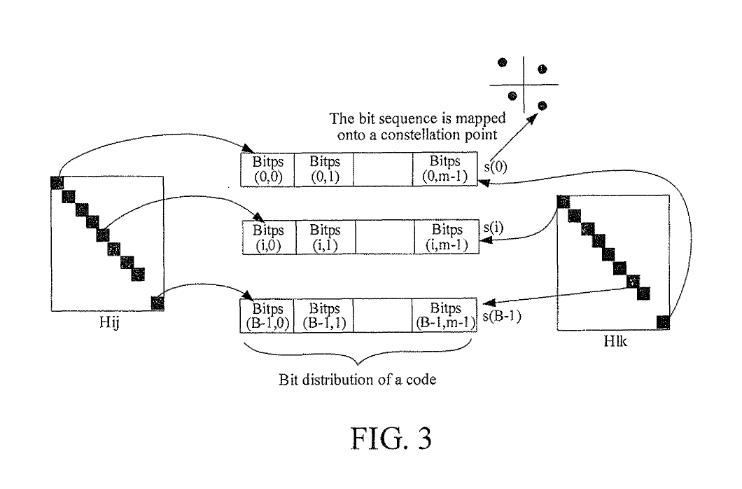

FIG. 3 is a schematic view of a relation among bits, mapping symbols and check sub-matrixes in a novel BICM structure according to the present invention.

As shown in FIG. 3, a bit sequence [bitps(i,0), . . . , bitps(i,m−1)] with the length being m is mapped through a mapping manner to obtain a mapping symbol s(i), for example, a bit sequence [bitps(0,0), bitps(0,1), . . . , bitps(0,m−1)] is mapped to obtain a mapping symbol s(0), a bit sequence [bitps(i,0), bitps(1,1), . . . , bitps(i,m−1)] is mapped to obtain a mapping symbol s(i), a bit sequence [bitps(B,0), bitps(B,1), . . . , bitps(B,m−1)] is mapped to obtain a mapping symbol s(B−1), and the size of a set of the mapping symbols s(i) is 2^{m}.

Specifically, in the present invention, the mapping bits at the same position in all the mapping symbols s(i) of a subset Sᵣ=[s(0), . . . s(i), . . . s(B−1)] of the mapping symbols correspond to the same check sub-matrix. As shown in FIG. 3, a first mapping bit in all the mapping symbols s(i) corresponds to a check sub-matrix Hᵢⱼ . . . , and a last mapping bit of all the mapping symbols s(i) corresponds to a check sub-matrix Hₗₖ. In this way, in the BICM structure, the number of the check sub-matrixes is m. Correspondingly, the parallel soft demodulation performed on the above subset Sᵣ of the mapping symbols needs to read m bit external information blocks, thereby reducing the processing complexity and correspondingly improving the decoding performance.

In order to achieve parallel update of all the receiving symbols, a rule of an interleaver in the structure needs to be defined.

A mapping manner of the interleaver is as follows:

Π={Iᵢₙ(i), i=0, . . . , N−1}→{Iₒᵤₜ(i), i=0, . . . , N−1}.

Here, Iᵢₙ is a time index of an input bit element, and Iₒᵤₜ is a time index of an output bit element.

The interleaver is decomposed as follows:

Π=Π₀∪Π₁∪ . . . ∪Π_{κ}

where, Πᵢ∩Πⱼ=Null, if i≠j, 0≦i, j<κ.

Here, it is required that the input of each sub-interleaver corresponds to a certain check sub-matrix, namely

∀i, Πᵢ:Iₘ(i)→Iₒ(i), 0≦i<κ

Iₘ(i)={Iᵢₙ(map1(i,j)), j=0, . . . , B−1}

Iₒ(i)={Iₒᵤₜ(map2(i,j)), j=0, . . . , B−1}

∃l,t, Iₘ(i) [symbol] Ω(l,t).

where, map1(i,j) represents an input time index corresponding to the j^{th} bit of the i^{th} sub-interleaver, and map2(i,j) represents an output time index corresponding to the j^{th} bit of the i^{th} sub-interleaver.

In the above case, classification of the sub-interleaver is as follows and the number of the classifications is L:

$$Γ = {⋃}_{0 \leq k < L} {Γ}_{k} , 0 < L \leq κ , {Γ}_{k} ⊆ \{ 0 , 1 , … , κ - 1 \}$$

$$if 0 \leq i , j < L , i \neq j , {Γ}_{i} ⋂ {Γ}_{j} = Null ,$$

where, an output bit sequence set of a sub-interleaver corresponding to each classification may be fully mapped onto the corresponding symbol. For example, a classification corresponds to i sub-interleavers, and then the number of mapping symbols onto which the corresponding bit sequence set is mapped is B·i/m.

It should be noted that, in the above description, the size of the sub-matrix Hᵢⱼ is described by taking the size (B*B) of the greatest sub-matrix of the check matrix as an example, but is not limited thereto, and in other embodiments, the size of the sub-matrix Hᵢⱼ may be a submultiple

$$\frac{B}{sub} * \frac{B}{sub}$$

of the greatest sub-matrix (B*B), where sub and

$$\frac{B}{sub}$$

both are integers,

Interleaving manners of the sub-interleaver may be group interleaving, convolutional interleaving, S interleaving or other interleaving manners.

When the output of each sub-interleaver is mapped to the symbol, the corresponding positions may be different, For example, the output of the first sub-interleaver is mapped to bitps(i,0), and the output of the second sub-interleaver is mapped to bitps(i+1,1), and so forth.

The selected check sub-matrixes shall be uniform as much as possible at a column direction, to fully use soft information during an iteration process.

The bit sequence [bitps(i,0), . . . , bitps(i,m−1)] is mapped to obtain the mapping symbol s(i), and the used mapping rule is Gray mapping, multidimensional mapping, non-Gray mapping or other manners.

In addition, although the mapping rule corresponding to the output of the sub-interleaver does not affect parallelism of the soft demodulation, in consideration of improving a system diversity effect, it is suggested to meet the following requirements:

$$∀ i , j , k , 0 \leq j , k < m - 1 , 0 \leq i < \frac{N}{m} - 1 , j \neq k , 0 \leq l , t < κ$$

$$if bitps ( i , j ) ∈ {I}_{0} ( l ) , bitps ( i , k ) ∈ {I}_{0} ( t )$$

$$then , l \neq t .$$

A specific example is used for description in the following.

A check matrix of an encoder based on the LDPC code is as follows:

$$H = [ \begin{matrix}{I}^{0} & 0 & {I}^{1} & 0 & {I}^{0} & {I}^{2} \\ 0 & {I}^{2} & {I}^{5} & {I}^{2} & 0 & 0 \\ {I}^{7} & {I}^{1} + {I}^{4} & 0 & {I}^{3} & 0 & {I}^{7} \\ {I}^{4} & 0 & 0 & 0 & {I}^{1} & {I}^{5}\end{matrix} ]$$

I is an 8*8 unit matrix, is a matrix obtained in the case that the unit matrix I is translated by i in circulation towards a right direction. In the check matrix, a bit position set corresponding to a sub-matrix, for example the first column, is as follows:

Ω(0,0)=Ω(0,2)=Ω(0,3)={0,1,2,3,4,5,6,7}.

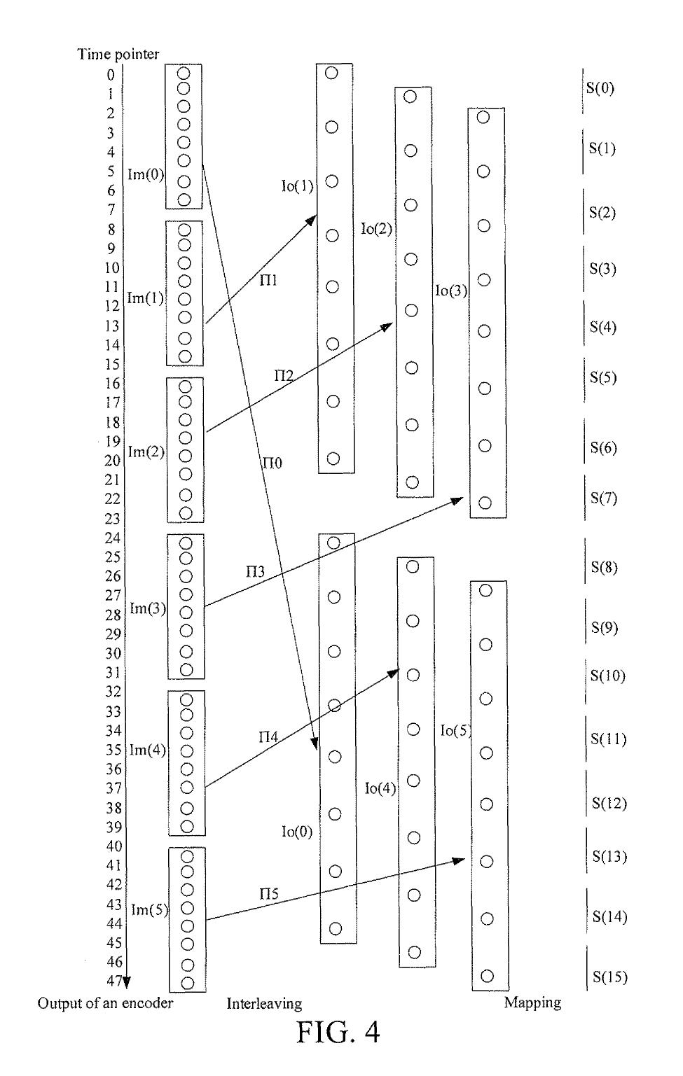

FIG. 4 is a state view of interleaving and mapping by a bit interleaver depending on an LDPC check matrix. As shown in FIG. 4, an input bit set of the first sub-interleaver is Iₘ(0)={0,1,2,3,4,5,6,7}, a position of an output bit set of the first sub-interleaver corresponding to the first sub-interleaver is Iₒ(0)={24,27,30,33,36,39,42,45}, Π₀ defines an one-to-one mapping relation between the input bit set Iₘ(0) of the first sub-interleaver and the position Iₒ(0) of the output bit set of the first sub-interleaver. A simplest mapping relation is defined as follows: 0->24, 1->27, 2->30, 3->33, 4->36, 5->39, 6->42, 7->45.

The input bit sets of other sub-interleavers and the output bit sets of the sub-interleavers also have the one-to-one mapping relation. Specifically, the input bit set Iₘ(1)={8,9,10,11,12,13,14,15} of the second sub-interleaver corresponds to the position Iₒ(1)={0,3,6,9,12,15,18,21} of the output bit set of the second sub-interleaver, and the mapping relation of the two is Π₁. The input bit set Iₘ(2)={16,17,18,19,20,21,22,23} of the third sub-interleaver corresponds to the position Iₒ(2)={1,4,7,10,13,16,19,22} of the output bit set of the third sub-interleaver, and the mapping relation of the two is Π₂. The input bit set Iₘ(3)={24,25,26,27,28,29,30,31} of the fourth sub-interleaver corresponds to the position Iₒ(3)={2,5,8,11,14,17,20,23} of the output bit set of the fourth sub-interleaver, and the mapping relation of the two is Π₃. The input bit set Iₘ(4)={32,33,34,35,36,37,38,39} of the fifth sub-interleaver corresponds to the position Iₒ(4)={25,28,31,34,37,40,43,46} of the output bit set of the fifth sub-interleaver, and the mapping relation of the two is Π₄. The input bit set Iₘ(5)={40,41,42,43,44,45,46,47} of the sixth sub-interleaver corresponds to the position Iₒ(5)={26,29,32,35,38,41,44,47} of the output bit set of the sixth sub-interleaver, and the mapping relation of the two is Π₅. In this way, the interleaving of the interleavers is implemented, and the interleaving manner may adopt group interleaving, convolutional interleaving or S interleaving.

Here, the input bit set of each sub-interleaver comprises 8 bits, 2^{m}=8, and m=3 is obtained, so the required number of the check sub-matrixes is 3. It is stipulated that three sub-interleavers are formed into a group, where the first group comprises the input bit set Iₘ(1)={8,9,10,11,12,13,14,15} of the second sub-interleaver, the input bit set Iₘ(2)={16,17,18,19,20,21,22,23} of the third sub-interleaver, and the input bit set Iₘ(3)={24,25,26,27,28,29,30,31} of the fourth sub-interleaver; and the second group comprises: the input bit set Iₘ(0)={0,1,2,3,4,5,6,7} of the first sub-interleaver, the position Iₒ(4)={25,28,31,34,37,40,43,46} of the output bit set of the fifth sub-interleaver, and the input bit set Iₘ(5)={40,41,42,43,44,45,46,47} of the sixth sub-interleaver, that is, the output of the sub-interleaver is divided into Γ₀={1,2,3} and Γ₀={0,4,5}.

Then, mapping is performed. Γ₀={1,2,3,} is mapped to obtain 8 mapping symbols comprising s(0), s(1), s(2), s(3), s(4), s(5), s(6), s(7), and Γ₀={1,2,3} is mapped to obtain 8 mapping signals comprising s(8), s(9), s(10), s(11), s(12), s(13), s(14), s(15). Each mapping symbol s(i) is obtained by mapping a bit sequence comprising 3 bits. Taking s(0), s(1), s(2), s(3), s(4), s(5), s(6), s(⁷) as an example, the position of output bit set of the mapping symbol s(0) is {0,1,2}, and the corresponding bit sequence is {8,16,24}. The position of the output bit sequence of the mapping symbol s(1) is {3,4,5}, and the corresponding bit sequence is {9,17,25}. The position of output bit set of the mapping symbol s(2) is {6,7,8}, and the corresponding bit sequence is {10,18,26}. The position of output bit set of the mapping symbol s(3) is {9,10,11}, and the corresponding bit sequence is {11,19,27}. The position of output bit set of the mapping symbol s(4) is {12,13,14}, and the corresponding bit sequence is {12,20,28}. The position of output bit set of the mapping symbol s(5) is {15,16,17}, and the corresponding bit sequence is {13,21,29}. The position of output bit set of the mapping symbol s(6) is {18,19,20}, and the corresponding bit sequence is {14,22,30}. The position of output bit set of the mapping symbol s(7) is {21,22,23}, and the corresponding bit sequence is {15,23,31}. The first bit set {8,9,10,11,12,13,14,15} of all the bit sequences of s(0), s(1), s(2), s(3), s(4), s(5), s(6), s(7) corresponds to the input bit set Iₘ(0)={0,1,2,3,4,5,6,7)} of the first interleaver; the second bit set {16,17,18,19,20,21,22,23} of all the bit sequences of s(0), s(1), s(2), s(3), s(4), s(5), s(6), s(7) corresponds to the input bit set Iₘ(2)={16,17,18,19,20,21,22,23} of the third sub-interleaver; and the third bit set {24,25,26,27,28,29,30,31} of all the bit sequences of s(0), s(1), s(2), s(3), s(4), s(5), s(6), s(7) corresponds to the input bit set Iₘ(3)={24,25,26,27,28,29,30,31} of the fourth sub-interleaver.

In the above description, The bit sequence [bitps(i,0), . . . , bitps(i,m−1)] is mapped to the constellation point s(i), and the used mapping rule can be Gray mapping, multidimensional mapping, non-Gray mapping or other manners.

The finally modulated signal is a modulated octal signal, such as 8PSK or 8ASK.

To sum up, in the IMPLEMENTATION-ORIENTED METHOD of BICM based on the LDPC check matrix, each bit sequence [bitps(i,0), . . . , bitps(i,m−1)] with the length being m is mapped to obtain the mapping symbol s(i), and the mapping bits at the same position in all of the mapping symbols correspond to the same check sub-matrix (that is, the check sub-matrix at the same mark is mapped onto the mapping bits at a certain mark in all the mapping symbols s(i)). In this way, subsequently the receiver easily reads the bit external information blocks corresponding to the mapping symbols during parallel soft demodulation, thereby easily implementing decoding feedback and fully exerting joint receiving performance.

The above description of the detailed embodiments is only to illustrate the principles and effects of the present invention, and is not to limit the scope of the present invention. Accordingly, all modifications completed by those skilled in the art should fall within the protection scope of the present invention defined by the appended claims.

1. An IMPLEMENTATION-ORIENTED METHOD of Bit Interleaved Coded Modulation (BICM) based on a Low-Density Parity-Check (LDPC) check matrix, comprising:
providing an LDPC code having a block check matrix, wherein the block check matrix is divided into one or more sub-matrixes Hᵢⱼ, and the size of the sub-matrix Hᵢⱼ is C*C;
constructing a BICM structure; in the BICM structure, mapping an i^{th} bit sequence [bitps(i,0), . . . , bitps(i,m−1)] with the length being m to obtain a mapping symbol s(i), wherein the size of a set of the mapping symbols s(i) is 2^{m}; and enabling mapping bits of a subset Sᵣ=[s(0), . . . s(i), . . . s(C−1)] of the mapping symbols to correspond to m check sub-matrixes.

2. The IMPLEMENTATION-ORIENTED METHOD according to claim 1, wherein the enabling the mapping bits of the subset Sᵣ=[s(0), . . . s(i), . . . s(C−1)] of the mapping symbols to correspond to m check sub-matrixes comprises: enabling mapping bits at the same position in all the mapping symbols s(i) of the subset Sᵣ=[s(0), . . . s(i), . . . s(C−1)] of the mapping symbols to correspond to the same check sub-matrix, wherein the number of the check sub-matrixes is m.

3. The IMPLEMENTATION-ORIENTED METHOD according to claim 1, wherein in the BICM structure, a mapping method of an interleaver comprises:
Π={Iᵢₙ(i),i=0, . . . , N−1}→{Iₒᵤₜ(i), i=0, . . . , N−1},
wherein, Iᵢₙ is a time index of an input bit, and Iₒᵤₜ is a time index of a corresponding output bit; and
the interleaver is decomposed as follows:
Π=Π₀∪Π₁∪ . . . ∪Π_{κ},
wherein, Πᵢ∪Πⱼ=Null, if i≠j, 0≦i, j<κ.

4. The IMPLEMENTATION-ORIENTED METHOD according to claim 3, wherein input of each sub-interleaver corresponds to one check sub-matrix, that is:
∀i, Πᵢ:Iₘ(i)→Iₒ(i), 0≦i<κ,
Iₘ(i)={Iᵢₙ(map1(i,j)), j=0, . . . , C−1},
Iₒ(i)={Iₒᵤₜ(map2(i,j)), j=0, . . . , C−1},
∃l, t, Iₘ(i) [symbol] Ω(l,t);
wherein, map1(i,j) represents an input time index corresponding to the j^{th} bit of the i^{th} sub-interleaver, and map2(i,j) represents an output time index corresponding to the j^{th} bit of the sub-interleaver.

5. The IMPLEMENTATION-ORIENTED METHOD according to claim 4, wherein classification of the sub-interleavers is as follows and the number of the classifications is L:
$$Γ = {⋃}_{0 \leq k < L} {Γ}_{k} , 0 < L \leq κ , {Γ}_{k} ⊆ \{ 0 , 1 , … , κ - 1 \}$$
$$if 0 \leq i , j < L , i \neq j , {Γ}_{i} ⋂ {Γ}_{j} = Null ,$$
wherein, an output bit set of a sub-interleaver corresponding to each classification is fully mapped onto the corresponding symbol.

6. The IMPLEMENTATION-ORIENTED METHOD according to claim 5, wherein a mapping rule corresponding to the output of the sub-interleaver comprises:
$$∀ i , j , k , 0 \leq j , k < m - 1 , 0 \leq i < \frac{N}{m} - 1 , j \neq k , 0 \leq l , t < κ$$
$$if bitps ( i , j ) ∈ {I}_{0} ( l ) , bitps ( i , k ) ∈ {I}_{0} ( t )$$
$$then , l \neq t .$$

7. The IMPLEMENTATION-ORIENTED METHOD according to claim 3, wherein a mapping manner of the sub-interleaver comprises: group interleaving, convolutional interleaving and S interleaving.

8. The IMPLEMENTATION-ORIENTED METHOD according to claim 1, wherein the size of the sub-matrix Hᵢⱼ is the size of the greatest sub-matrix B*B of the check matrix or a submultiple
$$\frac{B}{sub} * \frac{B}{sub}$$
of the greatest sub-matrix, wherein sub and
$$\frac{B}{sub}$$
both are integers.

9. The IMPLEMENTATION-ORIENTED METHOD according to claim 1, wherein the bit sequence [bitps(i,0), . . . , bitps(i,m−1)] is mapped to obtain the mapping symbol s(i) through the following mapping manners: Gray mapping, non-Gray mapping, multi-dimensional mapping, space-time mapping, space-time-frequency mapping or others.

10. The IMPLEMENTATION-ORIENTED METHOD according to claim 2, wherein in the BICM structure, a mapping method of an interleaver comprises:
Π={Iᵢₙ(i), i=0, . . . , N−1}→{Iₒᵤₜ(i), i=0, . . . , N−1},
wherein, Iₘ is a time index of an input bit, and Iₒᵤₜ is a time index of a corresponding output bit; and
the interleaver is decomposed as follows:
Π=Π₀∪Π₁∪ . . . ∪Π_{κ},
wherein, Πᵢ∩Πⱼ=Null, if i≠j, 0≦i, j<κ.

11. The IMPLEMENTATION-ORIENTED METHOD according to claim 10, wherein input of each sub-interleaver corresponds to one check sub-matrix, that is:
∀i, Π₁:Iₘ(i)→Iₒ(i), 0≦i<κ,
Iₘ(i)={Iᵢₙ(map1(i,j)), j=0, . . . , C−1},
Iₒ(i)={Iₒᵤₜ(map2(i,j)), j=0, . . . , C−1},
∃l,t, Iₘ(i) [symbol] Ω(l,t);
wherein, map1(i, j) represents an input time index corresponding to the j^{th} bit of the i^{th} sub-interleaver, and map2(i, j) represents an output time index corresponding to the j^{th} bit of the i^{th} sub-interleaver.

12. The IMPLEMENTATION-ORIENTED METHOD according to claim 11, wherein classification of the sub-interleavers is as follows and the number of the classifications is L:
$$Γ = {⋃}_{0 \leq k < L} {Γ}_{k} , 0 < L \leq κ , {Γ}_{k} ⊆ \{ 0 , 1 , … , κ - 1 \}$$
$$if 0 \leq i , j < L , i \neq j , {Γ}_{i} ⋂ {Γ}_{j} = Null ,$$
wherein, an output bit set of a sub-interleaver corresponding to each classification is fully mapped onto the corresponding symbol.

13. The IMPLEMENTATION-ORIENTED METHOD according to claim 12, wherein a mapping rule corresponding to the output of the sub-interleaver comprises:
$$∀ i , j , k , 0 \leq j , k < m - 1 , 0 \leq i < \frac{N}{m} - 1 , j \neq k , 0 \leq l , t < κ$$
$$if bitps ( i , j ) ∈ {I}_{0} ( l ) , bitps ( i , k ) ∈ {I}_{0} ( t )$$
$$then , l \neq t .$$

14. The IMPLEMENTATION-ORIENTED METHOD according to claim 13, wherein a mapping manner of the sub-interleaver comprises: group interleaving, convolutional interleaving and S interleaving.
